(19) United States
(12) Patent Application Publication
(10) Pub. No.: US 2024/0413208 A1
(43) Pub. Date: Dec. 12, 2024

(54) SINTERED BODY, SEMICONDUCTOR SUBSTRATE, SEMICONDUCTOR DEVICE, AND METHOD OF MANUFACTURING THEREOF

(71) Applicant: ROHM CO., LTD., Kyoto (JP)

(72) Inventors: Takuji MAEKAWA, Kyoto-shi (JP); Keiju SATO, Kyoto-shi (JP)

(73) Assignee: ROHM CO., LTD., Kyoto (JP)

(21) Appl. No.: 18/808,726

(22) Filed: Aug. 19, 2024

Related U.S. Application Data
(63) Continuation of application No. PCT/JP2023/007632, filed on Mar. 1, 2023.

(30) Foreign Application Priority Data
Mar. 10, 2022 (JP) 2022-037192

(51) Int. Cl. H01L 29/16; C30B 29/36; H01L 29/66; H01L 29/739; H01L 29/78; H01L 29/872; H01L 33/00; H01L 33/34

(52) U.S. Cl. CPC H01L 29/1608; C30B 29/36; H01L 29/66143; H01L 29/66333; H01L 29/66712; H01L 29/7397; H01L 29/7813; H01L 29/872; H01L 33/0054; H01L 33/34

(57) ABSTRACT

A molding is formed by laminating an aggregate of SiC and a paste containing Si and C powders on an epitaxial layer of SiC formed on a support substrate of SiC to form an intermediate sintered body in which polycrystalline SiC is produced from the Si and C powders by reaction sintering, free Si is carbonized to SiC to form a sintered body layer, and the support substrate is removed from the epitaxial layer to form a semiconductor substrate in which the epitaxial layer and the sintered body layer are laminated.

### CROSS REFERENCE TO RELATED APPLICATIONS AND INCORPORATION BY REFERENCE

This is a continuation application (CA) of PCT Application No. PCT/JP2023/007632, filed on Mar. 1, 2023, which claims priority to Japan Patent Application No. P2022-037192 filed on Mar. 10, 2022 and is based upon and claims the benefit of priority from prior Japanese Patent Application No. P2022-037192 filed on Mar. 10, 2022 and PCT Application No. PCT/JP2023/007632, filed on Mar. 1, 2023; the entire contents of each of which are incorporated herein by reference.

### TECHNICAL FIELD

This embodiment relates to a sintered body, a semiconductor substrate, a semiconductor device, and a method of manufacturing thereof.

### BACKGROUND

Conventionally, silicon carbide (SiC) devices such as Schottky barrier diodes (SBDs), MOSFETs, and insulated gate bipolar transistors (IGBTs) have been provided for power control applications. SiC semiconductor substrates on which such SiC devices are formed are sometimes fabricated by bonding a single-crystal SiC semiconductor substrate to a polycrystalline SiC semiconductor substrate in order to reduce manufacturing costs and provide desired physical properties. In addition, a single-crystal SiC semiconductor substrate is sometimes bonded to a SiC sintered body, and the SiC sintered body is sometimes fabricated by a reaction-sintering method.

### BRIEF DESCRIPTION OF THE DRAWINGS

FIG. 1 is a flowchart showing a series of steps in a method of manufacturing a semiconductor substrate.

FIG. 2A is a process flow diagram of a semiconductor substrate manufacturing method.

FIG. 2B is a process flow diagram of a semiconductor substrate manufacturing method.

FIG. 2C is a process flow diagram of a semiconductor substrate manufacturing method.

FIG. 2D is a process flow diagram of a semiconductor substrate manufacturing method.

FIG. 2E is a process flow diagram of a semiconductor substrate manufacturing method.

FIG. 3A is a schematic diagram illustrating reaction sintering and carbonization steps in a method of manufacturing a semiconductor substrate.

FIG. 3B is a schematic diagram illustrating reaction sintering and carbonization steps in a method of manufacturing a semiconductor substrate.

FIG. 3C is a schematic diagram illustrating reaction sintering and carbonization steps in a method of manufacturing a semiconductor substrate.

FIG. 4 is a schematic diagram illustrating a SiC film covering a sintered body layer of a semiconductor substrate.

FIG. 5 is a cross-sectional view showing a structure of a Schottky barrier diode.

FIG. 6 is a cross-sectional view showing a structure of a trench gate type MOSFET.

FIG. 7 is a cross-sectional view showing a structure of a planar gate type MOSFET.

### DESCRIPTION OF EMBODIMENTS

Hereinafter, a sintered body, a semiconductor substrate, a semiconductor device according to the embodiment and a manufacturing method thereof will be described in detail with reference to the drawings.

A sintered body according to the embodiment includes an aggregate of SiC and polycrystalline SiC which fills a gap in the aggregate.

A semiconductor substrate according to the embodiment uses the sintered body and includes a single crystal layer composed of a single crystal of SiC and a sintered body layer of SiC composed of a sintered body laminated on the single crystal layer. The single crystal layer may be composed of an epitaxial layer of SiC. A group V element may be added to the SiC constituting the single crystal layer and the SiC constituting the sintered body layer. A protective film of SiC covering the sintered body layer may be further included.

A semiconductor device according to the embodiment uses the semiconductor substrate, and in the semiconductor substrate, the single crystal layer is a drift layer and the sintered body layer is a substrate layer. In the sintered body layer, a range up to a predetermined distance from an interface with the single crystal layer may be a buffer layer. The semiconductor device may include at least one of a Schottky barrier diode, a MOSFET, an IGBT and an LED.

A method of manufacturing a sintered body according to the embodiment includes a step for reaction-sintering an aggregate composed of SiC and a paste containing Si and C powders to produce polycrystalline SiC from the Si and C powders, and a step for carbonizing free Si into SiC by impregnating the reaction-sintered paste with a gas containing C. A chemical composition ratio of the Si and C powders may be adjusted so that the reaction-sintered paste contains free Si. A step of impregnating the reaction-sintered paste with a gas containing Si to contain free Si may be further included.

A method of manufacturing a semiconductor substrate according to the embodiment uses the method of manufacturing a sintered body. The paste is applied to be laminated on a single crystal layer of SiC, and the paste is obtained as a sintered body of SiC according to the method of manufacturing the sintered body. The sintered body constitutes a sintered body layer laminated on the single crystal layer. A step for forming an epitaxial layer on a supporting substrate of SiC is further included, and the single crystal layer may be constituted by an epitaxial layer. A step for removing a semiconductor substrate composed of the single crystal layer and the sintered body layer from the supporting substrate may be further included. An impurity of a group V element is added to the SiC constituting the single crystal layer, and group V elements may also be added to the paste. A step for forming a protective film of the SiC covering the sintered body layer may be further included.

The method of manufacturing a semiconductor device according to the embodiment further includes, following a series of steps in the method of manufacturing a semiconductor substrate, a step for forming a semiconductor device in which in the semiconductor substrate, the single crystal layer is a drift layer and the sintered body layer is a substrate layer. A range of the sintered body layer up to a predetermined distance from an interface with the single crystal layer may be a buffer layer. The semiconductor device may include at least one of a Schottky barrier diode, a MOSFET, an IGBT and an LED.

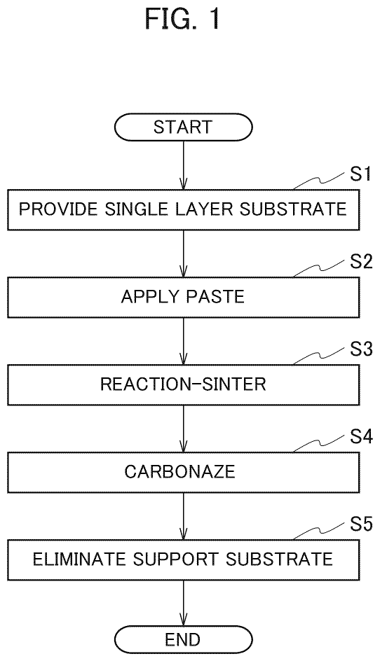

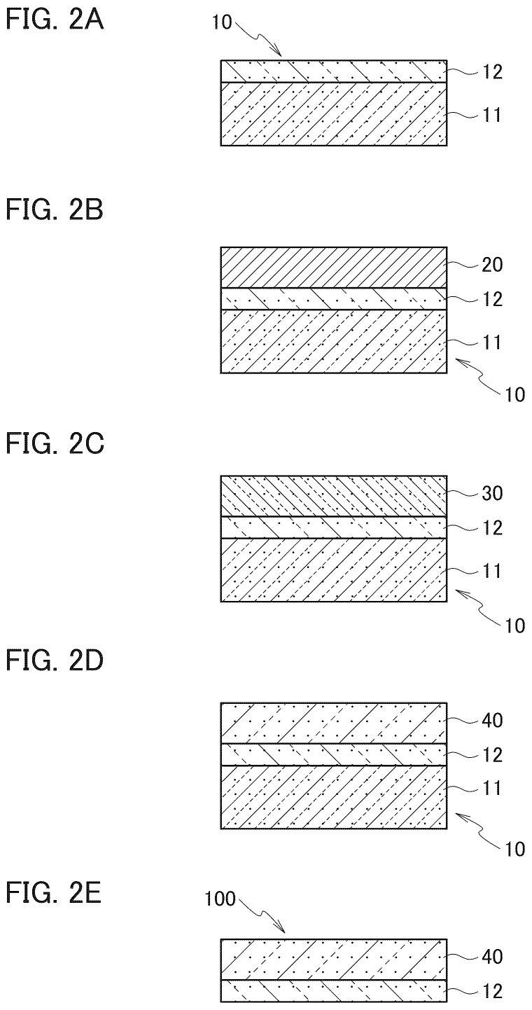

FIG. 1 is a flowchart illustrating a series of steps in a method of manufacturing a semiconductor substrate according to the embodiment. FIGS. 2A to 2E are process flow diagrams of a method of manufacturing a semiconductor substrate according to the embodiment. The sintered body and the semiconductor substrate in the embodiment are assumed to be an n-type semiconductor to which an impurity due to a group V element is added for use in a conductor substrate, but for use in an insulator substrate, the sintered body and the semiconductor substrate may be formed as an intrinsic semiconductor without such an impurity.

In the first step S1, an epitaxial layer to be a single crystal layer of SiC is provided. As shown in FIG. 2A, an epitaxial layer 12 according to the embodiment may be provided as a substrate 10 formed on a top surface of a support substrate 11 of a suitable SiC single crystal and having the epitaxial layer 12 and support substrate 11 integrally formed. The epitaxial layer 12 may have any structure of 4H—SiC, 6H—SiC, 2H—SiC, or 3C—SiC. The epitaxial layer 12 is an n-type semiconductor to which an impurity of a pentavalent group V element such as P, As, and N is added. The support substrate 11 may be a SiC single crystal formed by a sublimation method and the like. The epitaxial layer 12 may be formed by remote epitaxial growth in which a film of graphene is interposed on the top surface of the support substrate 11. The epitaxial layer 12 by the remote epitaxial growth can be easily separated from the support substrate 11.

In step S2, a paste is applied to a top surface of the epitaxial layer 12 provided in step S1 to form a molding 20 of the paste, as shown in FIG. 2B. The paste is constituted by mixing an aggregate made of SiC and a polycrystalline SiC raw material made of the Si and C powders. The aggregate of SiC is provided by the SiC powder having a particle size of about 10 μm. The Si and C powders are reaction-sintered to polycrystalline SiC in a later step, and the particle size is about 1 μm because the reaction is not sufficient when the particle size is large and the surface oxidation is affected when the particle size is small. The aggregate of SiC with the particle size of about 10 μm and the Si and C powders with the particle size of about 1 μm are contained in the paste in a weight ratio of 50:50. The Si and C powders are adjusted to increase the chemical composition ratio of Si to C so that the SiC produced by the reaction sintering becomes Si-rich. In order to make the SiC obtained by the reaction sintering into an n-type semiconductor, SiN containing the group V element N as an impurity is also added to the raw material as SiN powder having a particle size of 1 μm. Further, polyvinyl alcohol and the like are added as an auxiliary agent.

The paste containing the aggregate and the raw material in this manner is applied to the top surface of the epitaxial layer 12 to a predetermined height to form the molding 20 by the paste. Application of the paste is performed in an atmosphere at 500° C. in a heating furnace. In step S2, the molding 20 is formed by, but not limited to, applying the paste, and the molding 20 of the paste may be formed by other methods such as pressure forming or laminating sheets.

In step S3, the molding 20 of the paste formed on the top surface of the epitaxial layer 12 in step S2 is reaction-sintered to form an intermediate sintered body 30, as shown in FIG. 2C. The molding 20 of the paste formed on the top surface of the epitaxial layer 12 is heated in an inert gas atmosphere at a temperature of 1,500° C. in the heating furnace, and the Si and C powders as raw materials contained in the paste are reaction-sintered to polycrystalline SiC. By the reaction sintering of the Si and C powders, polycrystalline SiC is formed in a gap in the aggregate of SiC contained in the intermediate sintered body 30. SiN is added to the raw Si and C powders, so that the formed polycrystalline SiC becomes an n-type semiconductor. The raw Si and C powders are adjusted to increase the chemical composition ratio of Si to C, so that the formed polycrystalline SiC becomes Si-rich containing free Si. In the gap of the SiC aggregate in the intermediate sintered body 30, pores are formed along with the polycrystalline SiC, and a molding density is 95% due to the formation of pores. The molding density can be adjusted by the amount of auxiliary agent added to the raw material of the paste. When the molding density decreases from 100% to 90%, the strength of the intermediate sintered body 30 halves. In addition, the volume of the intermediate sintered body 30 from the molded body 20 of the paste decreases by about 20% by the reaction sintering. Therefore, processing of the intermediate sintered body 30 may be necessary.

In step S4, the intermediate sintered body 30 formed in step S3 is carbonized to produce a final sintered body, as shown in FIG. 2D. The sintered body constitutes a sintered body layer 40 laminated on the top surface of the epitaxial layer 12. The intermediate sintered body 30 fabricated in step S3 is Si-rich containing free Si and has a molding density of 95% due to the formation of pores. The intermediate sintered body 30 formed on the top surface of the epitaxial layer 12 is supplied with a flow of CH₄ gas in an inert gas atmosphere in the heating furnace at a temperature ranging from 1,200 to 1,800° C., for example, 1,600° C. Free Si contained in the intermediate sintered body 30 is carbonized to SiC by CH₄ gas impregnated the intermediate sintered body 30 through pores. Such carbonization results in a final sintered body layer 40 composed of a single-crystal SiC aggregate and a polycrystalline SiC filling the gap between the single crystals. As mentioned above, the sintered body layer 40 is a polycrystalline n-type semiconductor as a whole, since the polycrystalline SiC produced by the reaction sintering is an n-type semiconductor.

In step S5, the support substrate 11 supporting the epitaxial layer 12 is removed, as shown in FIG. 2E. For example, a bottom surface of the epitaxial layer 12 and the top surface of the support substrate 11 may be divided by a wedge, or may be separated by other methods. If the epitaxial layer 12 is formed on the support substrate 11 by remote epitaxial growth through a graphene film, the epitaxial layer 12 can be easily removed from the support substrate 11 by applying an external force to the support substrate 11. By removing the support substrate 11 supporting the epitaxial layer 12, a final semiconductor substrate 100 is obtained in which the epitaxial layer 12 and the sintered body layer 40 are laminated.

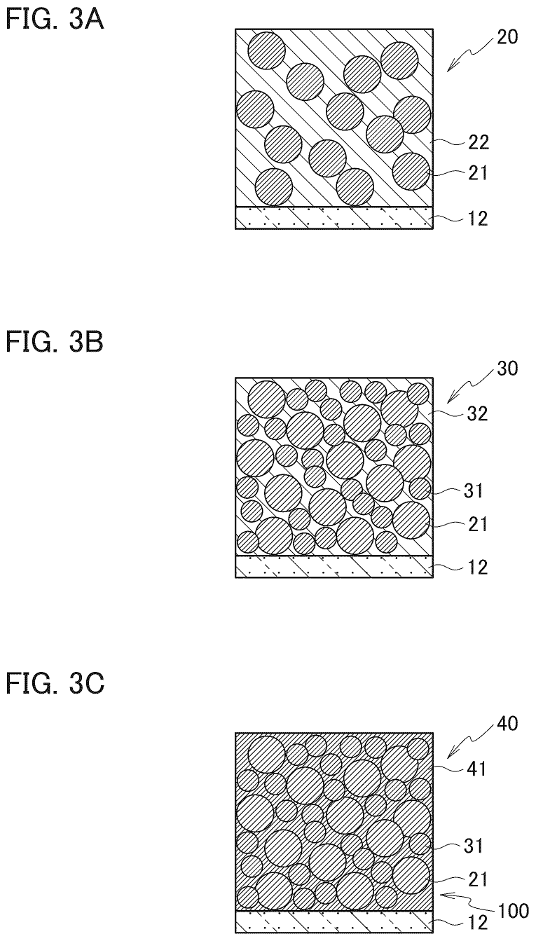

FIGS. 3A to 3C are schematic diagrams for illustrating reaction sintering and carbonization steps in a method of manufacturing a semiconductor substrate. FIG. 3A is a diagram for illustrating a structure of a molding 20 formed by a paste on the top surface of the epitaxial layer 12 in step S2. As described above, the paste is constituted by mixing an aggregate 21 made of SiC powder having a particle size of about 10 μm and a raw material 22 reaction-sintered to SiC made of the Si and C powders having the particle size of about 1 μm. In the raw material 22, SiN containing a group V element N as an impurity is also added to SiN powder having a particle size of 1 μm so that the SiC obtained by sintering is an n-type semiconductor. In addition, polyvinyl alcohol is also added to the raw material 22 as an auxiliary agent. In FIG. 3A, the molding 20 formed on the top surface of the epitaxial layer 12 includes an aggregate 21 made of SiC powder, and the gap in the aggregate 21 is filled by the raw material 22 such as the Si and C powders.

FIG. 3B is a diagram for illustrating the structure of the intermediate sintered body 30 in which a raw material 22 such as Si and C powders included in the molding 20 is reaction-sintered to polycrystalline SiC by the reaction sintering in step S3. In the molding 20 formed by the paste shown in FIG. 3A, the Si and C powders of the raw material 22 filling the gap in the aggregate are reaction-sintered to SiC to fabricate polycrystalline SiC particles 31. The SiN powder is added to the Si and C powders of the raw material 22, the polycrystalline SiC particles 31 are n-type semiconductors. In the intermediate sintered body 30, the gap 32 in the aggregate 21 and between the SiC particles 31 are formed by free Si or pores remaining after the reaction sintering. As described above, the Si and C powders of the raw material 22 are adjusted to be Si-rich, so that free Si remains after reaction sintering. Further, the porosity can be adjusted by the amount of auxiliary agent added to the paste material.

FIG. 3C is a diagram for illustrating a structure of the final sintered body layer 40 in which free Si contained in the intermediate sintered body 30 is SiC carbonized in step S4. The free Si is carbonized into SiC by carbon supplied by CH₄ gas, for example. In this way, a sintered body layer 40 of the semiconductor substrate 100 is produced. The sintered body layer 40 is an n-type semiconductor as a whole, since it contains polycrystalline SiC of an n-type semiconductor.

The embodiment does not use normal temperature bonding or diffusion bonding for bonding the epitaxial layer 12 and the sintered body layer 40. Therefore, precision polishing of the bonding surface for normal temperature bonding or diffusion bonding is not required, so that the cost can be reduced and the yield can be improved. Moreover, the sintered body layer 40 does not contain Al₂O₃, which has low corrosion resistance, so that corrosion resistance can be ensured.

In this embodiment, the sintered body layer 40 of SiC is produced by reaction sintering. Therefore, warping problems such as those observed in SiC layers deposited by CVD do not occur. The volume change of the sintered body layer 40 fabricated by reaction sintering is relatively small, so that the need for processing after reaction sintering can be reduced. Moreover, free Si remaining in SiC after reaction sintering is carbonized to SiC by supplying gas containing C. Therefore, free Si does not remain, so that strength of the sintered body layer 40 at high temperature can be ensured. Further, free Si is carbonized to SiC, so that porosity does not increase and oxidation resistance related to porosity is also ensured.

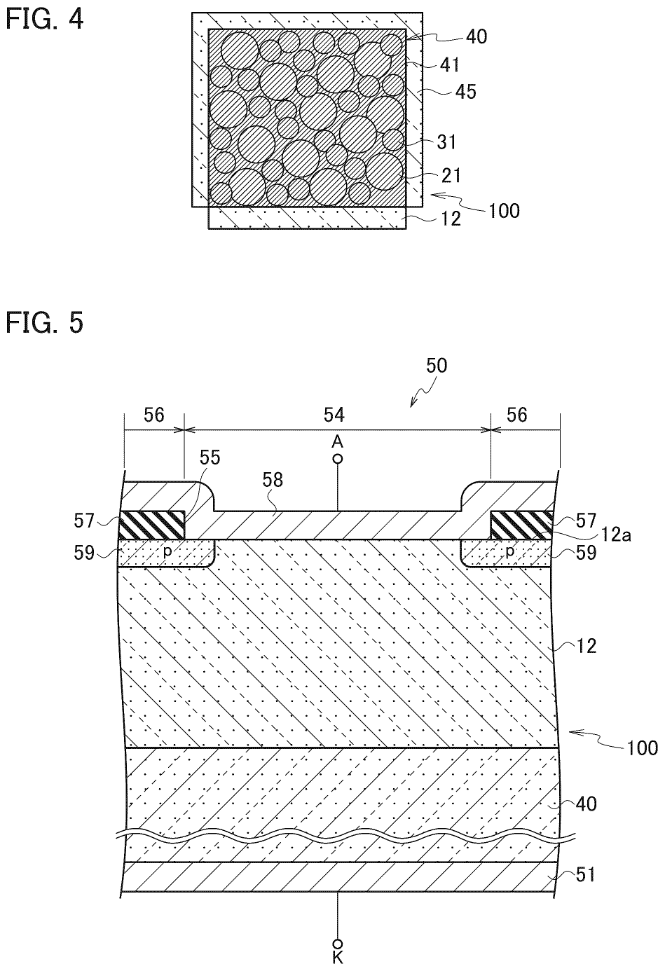

FIG. 4 is a diagram showing an SiC protective film 45 covering the sintered body layer 40. In a series of steps in the method of manufacturing the semiconductor substrate shown in FIG. 1, SiC may be deposited to cover the surface of the sintered body layer 40 by CVD, for example, before removing the supporting substrate 11 in step S5 following carbonization in step S4 to form the protective film 45. In the sintered body layer 40 formed by carbonization in step S4, there are pores as well as polycrystalline SiC in the SiC aggregate 21, and the pores are exposed on the surface of the sintered body layer 40. By forming the protective film 45 on the surface of the sintered body layer 40, the pores exposed on the surface of the sintered body layer 40 are covered, and breakage and dust generation from the pores are prevented. Furthermore, the pores are covered by the protective film 45, so that oxidation resistance is also ensured.

In step S2 of applying the paste in the series of steps in the method of manufacturing the semiconductor substrate shown in FIG. 1, the Si and C powders of the raw materials are adjusted to increase the chemical composition ratio of Si to C so that the polycrystalline SiC produced in step S3 of the reaction sintering is Si-rich containing free Si. Instead of adjusting the chemical composition ratio of the Si and C powders of the raw materials in step S2, or in addition to adjusting the chemical composition ratio, a silicification step may be provided after the reaction sintering in step S3 and before the carbonization in step S4, and Si may be added to the intermediate sintered body 30 fabricated in step S3 to make it Si-rich.

In the silicification step, an Si sheet containing the Si powder is laminated on the intermediate sintered body 30. The laminated intermediate sintered body 30 and the Si sheet are heated to 1,414° C., the melting point of Si, or higher, so that the melted Si is impregnated the intermediate sintered body 30 through pores. At 1,400° C. or higher, C contained in the intermediate sintered body 30 and Si supplied from the Si sheet are reaction-sintered to SiC. In the reaction sintering accompanying such a silicification step, the volume change of the intermediate sintered body 30 is ±1%, which is small compared with −20% of the reaction sintering in step S3. Therefore, the intermediate sintered body 30 after the silicification step does not need to be processed by the volume change. In the carbonization step S4 following the silicification step, it is desirable to carbonize the silicified intermediate sintered body 30 at 1,800° C. In the silicification step, instead of overlaying Si sheets and heating the intermediate sintered body 30, the intermediate sintered body 30 may be ground and remolded after adding the Si powder.

By providing such a silicification step separately, it is possible to adjust the content of Si contained in the intermediate sintered body 30 to a desired content before the carbonization step S4. Therefore, it is possible to set characteristics of the sintered body layer 40 such as porosity in the final sintered body layer 40 obtained by the subsequent carbonization step S4.

The semiconductor substrate according to the embodiment can be used for manufacturing various semiconductor devices, for example. In the semiconductor device, a single crystal layer of SiC can be used as a drift layer, and a sintered body layer composed of polycrystalline SiC can be used as a substrate layer in the semiconductor substrate. The sintered body layer up to a predetermined distance from the epitaxial layer can be used as a buffer layer. Examples of semiconductor devices include a Schottky Barrier Diode (SBD), a trench gate MOSFET, and a planar gate MOSFET. The semiconductor substrate can be applied to the semiconductor devices such as an IGBT, an LED, and the like.

FIG. 5 is a cross-sectional view showing a schematic structure of a Schottky barrier diode (SBD) 50 according to the embodiment. The SBD 50 includes a semiconductor substrate 100, in which an epitaxial layer 12 is a drift layer, and a sintered body layer 40 is a substrate layer. The sintered body layer 40 up to a predetermined distance from the epitaxial layer 12 may be used as a buffer layer. In the semiconductor substrate 100, both the epitaxial layer 12 and the sintered body layer 40 are composed of an n-type semiconductor, but the epitaxial layer 12 may be doped to an n⁻ type (with the impurity density, for example, from about 5×10¹⁴ cm⁻³ to about 5×10¹⁶ cm⁻³) and the sintered body layer 40 may be doped to an n⁺ type (with the impurity density, for example, from about 1×10¹⁸ cm⁻³ to about 1×10²¹ cm⁻³). For example, a group V element such as N, P, and As can be applied as an n-type doping impurity, and for example, TMA can be applied as a p-type doping impurity.

In FIG. 5, the bottom surface of the sintered body layer 40 includes a cathode electrode 51 to cover the entire surface thereof, and the cathode electrode 51 is connected to the cathode terminal K. A top surface 12a of the epitaxial layer 12 includes a contact hole 55 for exposing a part of the epitaxial layer 12 as an active region 54, and a field insulating film 57 is formed in a field region 56 surrounding the active region 54. The field insulating film 57 is made of SiO₂ (silicon oxide), but may be made of other insulating material such as silicon nitride (SiN). An anode electrode 58 is formed on the field insulating film 57, and the anode electrode 58 is connected to an anode terminal A.

A p-type Junction Termination Extension (JTE) structure 59 is formed near the top surface 12a (surface layer part) of the epitaxial layer 12 in contact with the anode electrode 58. The JTE structure 59 is formed along a contour of the contact hole 55 to straddle inside and outside the contact hole 55 of the field insulating film 57.

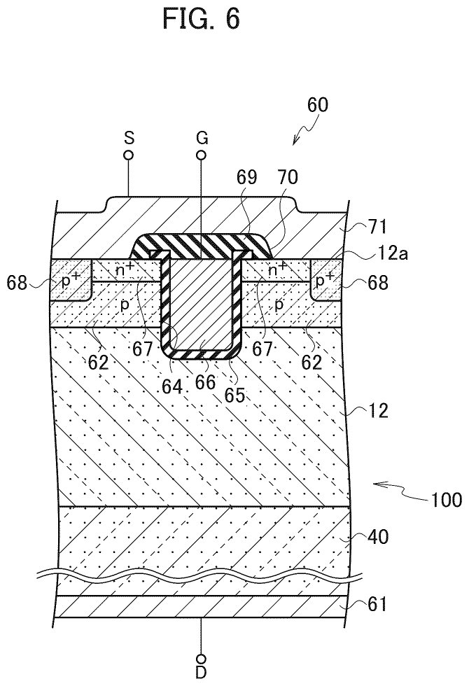

FIG. 6 is a cross-sectional view showing a schematic structure of a trench gate type MOSFET 60 according to the embodiment. The trench gate type MOSFET 60 includes a semiconductor substrate 100, in which an epitaxial layer 12 is a drift layer, and a sintered body layer 40 is a substrate layer. The sintered body layer 40 up to a predetermined distance from the epitaxial layer 12 may be used as a buffer layer. In the semiconductor substrate 100, both the epitaxial layer 12 and the sintered body layer 40 are composed of an n-type semiconductor, but the epitaxial layer 12 may be doped to an n⁻ type (with the impurity density, for example, from about 5×10¹⁴ cm⁻³ to about 5×10¹⁶ cm⁻³) and the sintered body layer 40 may be doped to an n⁺ type (with the impurity density, for example, from about 1×10¹⁸ cm⁻³ to about 1×10²¹ cm⁻³). For example, a group V element such as N, P, and As can be applied as an n-type doping impurity, and for example, TMA can be applied as a p-type doping impurity.

In FIG. 6, the bottom surface of the sintered body layer 40 includes a drain electrode 61 to cover the entire surface thereof, and the drain electrode 61 is connected to the drain terminal D. A p-type (with the impurity density, for example, from about 1×10¹⁶ cm⁻³ to about 1×10¹⁹ cm⁻³) body region 62 is formed near the top surface 12a (surface layer part) of the epitaxial layer 12. A portion of the epitaxial layer 12 facing to the sintered body layer 40 with respect to the body region 62 is an n type drain region in which the epitaxial layer 12 remains. A gate trench 64 is formed in the epitaxial layer 12. The gate trench 64 penetrates the body region 62 from the top surface 12a of the epitaxial layer 12, and its deepest part reaches the drain region composed of the epitaxial layer 12. A gate insulating film 65 is formed on the inner surface of the gate trench 64 and the top surface 12a of the epitaxial layer 12 to cover the entire inner surface of the gate trench 64. A gate electrode 66 is buried in the gate trench 64 by filling the inner surface of the gate insulating film 65 with polysilicon, for example. A gate terminal G is connected to the gate electrode 66.

An n⁺ type source region 67 forming a part of a side surface of the gate trench 64 is formed in a surface layer part of the body region 62. A p⁺ type (with the impurity density, for example, from about 1×10¹⁸ cm⁻³ to about 1×10²¹ cm⁻³) body contact region 68 penetrating the source region 67 from the top surface 12a and connected to the body region 62 is formed in the epitaxial layer 12. An interlayer insulating film 69 made of SiO₂ is formed on the epitaxial layer 12. A source electrode 71 is connected to a source region 67 and a body contact region 68 through a contact hole 70 formed in the interlayer insulating film 69. A source terminal S is connected to the source electrode 71.

By applying a predetermined voltage (voltage greater than or equal to the gate threshold voltage) to the gate electrode 66 with a predetermined potential difference generated between the source electrode 71 and the drain electrode 61 (between source and drain), a channel can be formed near the interface with the gate insulating film 65 in the body region 62 by an electric field from the gate electrode 66. Thus, a current can flow between the source electrode 71 and the drain electrode 61, and the trench gate type MOSFET 60 can be turned on.

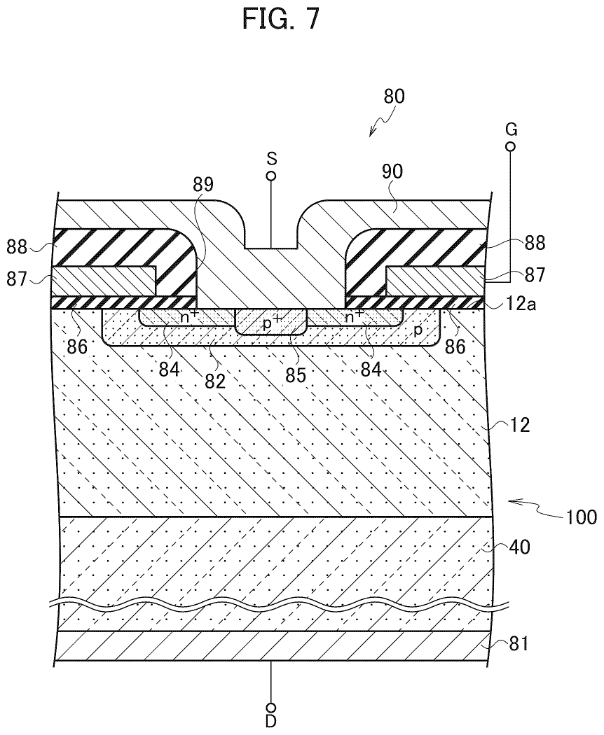

FIG. 7 is a cross-sectional view showing a schematic structure of the planar gate type MOSFET 80 according to the embodiment. The planar gate type MOSFET 80 includes a semiconductor substrate 100, in which the epitaxial layer 12 is a drift layer, and the sintered body layer 40 is a substrate layer. The sintered body layer 40 up to a predetermined distance from the epitaxial layer 12 may be used as a buffer layer. Although both the epitaxial layer 12 and the sintered body layer 40 of the semiconductor substrate 100 are composed of an n-type semiconductor, the epitaxial layer 12 may be doped to an n⁻ type (with the impurity density, for example, from about 5×10¹⁴ cm⁻³ to about 5×10¹⁶ cm⁻³) and the sintered body layer 40 may be doped to an n⁺ type (with the impurity density, for example, from about 1×10¹⁸ cm⁻³ to about 1×10²¹ cm⁻³). For example, a group V element such as N, P, and As can be applied as an n-type doping impurity, and for example, TMA can be applied as a p-type doping impurity.

In FIG. 7, a drain electrode 81 is formed on the bottom surface of the sintered body layer 40 to cover the entire area, and a drain terminal D is connected to the drain electrode 81. A p-type (with the impurity density, for example, from about 1×10¹⁶ cm⁻³ to about 1×10¹⁹ cm⁻³) body region 53 is formed in a well shape near the top surface 12a (surface layer part) of the epitaxial layer 12. A portion of the epitaxial layer 12 facing the SiC substrate 2 with respect to the body region 53 is an n⁻ type drain region in which a state after epitaxial growth remains.

In a surface layer part of a body region 82, an n⁺-type source region 84 is formed spaced from a periphery of the body region 82. A p⁺-type (with the impurity density, for example, from about 1×10¹⁸ cm⁻³ to about 1×10²¹ cm⁻³) body contact region 85 is formed inside the source region 84. The body contact region 85 penetrates the source region 84 in a depth direction and is connected to the body region 82. A gate insulating film 86 is formed on the top surface 12a of the epitaxial layer 12. The gate insulating film 86 covers a portion of the body region 82 surrounding the source region 84 (a peripheral edge of the body region 82) and an outer peripheral edge of the source region 84. A gate electrode 87 made of, for example, polysilicon is formed on the gate insulating film 86. The gate electrode 87 faces the peripheral edge of the body region 82 across the gate insulating film 86. A gate terminal G is connected to the gate electrode 87.

An interlayer insulating film 88 made of SiO₂ is formed on the epitaxial layer 12. A source electrode 90 is connected to the source region 84 and the body contact region 85 through a contact hole 89 formed in the interlayer insulating film 88. A source terminal S is connected to the source electrode 90. By applying a predetermined voltage (voltage greater than or equal to the gate threshold voltage) to the gate electrode 87 with a predetermined potential difference generated between the source electrode 90 and the drain electrode 81 (between source and drain), a channel can be formed near the interface with the gate insulating film 86 in the body region 82 by an electric field from the gate electrode 87. Thus, a current can flow between the source electrode 90 and the drain electrode 81, and the planar gate MOSFET 80 can be turned on.

The semiconductor device according to the embodiment uses a semiconductor substrate 100 for bonding the epitaxial layer 12 and the sintered body layer 40 without using normal temperature bonding or diffusion bonding. Precision polishing of the bonding surface for normal temperature bonding or diffusion bonding is not required for manufacturing the semiconductor substrate 100, so that the cost can be reduced and the yield can be improved. The sintered body layer 40 of the semiconductor substrate 100 does not contain Al₂O₃ having low corrosion resistance, so that corrosion resistance can be ensured. In the steps for manufacturing the semiconductor substrate 100, free Si is prevented from remaining in the sintered body layer 40 by the carbonization step, so that strength at high temperatures is ensured. Free Si is carbonized to SiC, so that porosity does not increase and oxidation resistance related to porosity is also ensured.

1. A sintered body of SiC, comprising:
an aggregate of SiC; and
polycrystalline SiC that fills a gap in the aggregate.

2. A semiconductor substrate using the sintered body according to claim 1, comprising:
a single crystal layer composed of a single crystal of SiC; and
a sintered body layer of SiC composed of the sintered body laminated on the single crystal layer.

3. The semiconductor substrate according to claim 2, wherein the single crystal layer is composed of an epitaxial layer of SiC.

4. The semiconductor substrate according to claim 2, wherein a group V element is added to the SiC constituting the single crystal layer and the SiC constituting the sintered body layer.

5. The semiconductor substrate according to claim 2, further comprising a protective film of SiC covering the sintered body layer.

6. A semiconductor device using the semiconductor substrate according to claim 2, wherein in the semiconductor substrate, the single crystal layer is a drift layer and the sintered body layer is a substrate layer.

7. The semiconductor device according to claim 6, wherein in the sintered body layer, a range up to a predetermined distance from an interface with the single crystal layer is a buffer layer.

8. The semiconductor device according to claim 6, wherein the semiconductor device comprises at least one of a Schottky barrier diode, a MOSFET, an IGBT and an LED.

9. A method of producing a sintered body of SiC,
reaction-sintering an aggregate composed of SiC and a paste containing Si and C powders to produce polycrystalline SiC from the Si and C powders; and
carbonizing free Si into SiC by impregnating the reaction-sintered paste with a gas containing C.

10. The method according to claim 9, wherein a chemical composition ratio of the Si and C powders is adjusted so that the reaction-sintered paste contains free Si.

11. The method according to claim 9, further comprising impregnating the reaction-sintered paste with a gas containing Si to contain free Si.

12. The method of manufacturing a semiconductor substrate using the method of manufacturing a sintered body according to claim 9, wherein
the paste is applied to be laminated on a single crystal layer of SiC;
the paste is obtained as a sintered body of SiC according to the method of manufacturing the sintered body; and
the sintered body constitutes a sintered body layer laminated on the single crystal layer.

13. The method according to claim 12, further comprising forming an epitaxial layer on a SiC support substrate, the single crystal layer being composed of the epitaxial layer.

14. The method according to claim 13, further comprising removing a semiconductor substrate composed of the single crystal layer and the sintered body layer from the support substrate.

15. The method according to claim 12, wherein an impurity a group V element is added to the SiC constituting the single crystal layer and a group V element is also added to the paste.

16. The method according to claim 12, further comprising forming a protective film of the SiC covering the sintered body layer.

17. A method of manufacturing a semiconductor device, comprising, following a series of the method of manufacturing a semiconductor substrate according to claim 12, forming a semiconductor device, wherein in the semiconductor substrate, the single crystal layer is a drift layer and the sintered body layer is a substrate layer.

18. The method of manufacturing a semiconductor device according to claim 17, wherein a range of the sintered body layer up to a predetermined distance from an interface with the single crystal layer is a buffer layer.

19. The method of manufacturing a semiconductor device according to claim 17, wherein the semiconductor device comprises at least one of a Schottky barrier diode, a MOSFET, an IGBT and an LED.
